(19) United States
(12) Patent Application Publication
(10) Pub. No.: US 2012/0153432 A1
(43) Pub. Date: Jun. 21, 2012

(54) SEMICONDUCTOR DEVICE AND METHOD FOR MANUFACTURING SAME

(75) Inventors: Yuji KARAKANE, Mie-ken (JP); Yoriyasu ANDO, Mie-ken (JP)

(73) Assignee: KABUSHIKI KAISHA TOSHIBA, Minato-ku (JP)

(21) Appl. No.: 13/233,716

(22) Filed: Sep. 15, 2011

(30) Foreign Application Priority Data
Dec. 17, 2010 (JP) 2010-281844

(51) Int. Cl. H01L 27/10; H01L 21/50

(52) U.S. Cl. 257/528; 438/118; 257/E27.07; 257/E21.502; 257/E21.499

(57) ABSTRACT

According to an embodiment, a semiconductor device includes a substrate, a control element provided on the substrate, a resin provided on the control element and a memory element provided above the control element. The memory element is in contact with the resin and electrically connected to the control element provided within a region therebeneath in plan view parallel to a surface of the substrate.

### CROSS-REFERENCE TO RELATED APPLICATIONS

This application is based upon and claims the benefit of priority from Japanese Patent Application No. 2010-281844, filed on Dec. 17, 2010; the entire contents of which are incorporated herein by reference.

### FIELD

Embodiments are generally related to a semiconductor device and a method for manufacturing the same.

### BACKGROUND

Semiconductor devices with a plurality of memory elements and a control element incorporated in one package are widely used. Thus, the capacity and convenience of semiconductor memory devices have been improved. On the other hand, the range of applications of these semiconductor devices has also expanded. They have been installed also on small equipment such as mobile terminals. Thus, downsizing of the package is desired.

If the memory elements, the control element and various passive components are laid out in a planar configuration on a substrate underlying the package, the package size inevitably increases. Thus, methods are proposed for three-dimensionally arranging these semiconductor elements and components. For instance, the control element can be stacked on a memory element having a larger chip size.

However, three-dimensional arrangement of semiconductor elements causes various problems. For instance, the control element arranged on the memory element needs to be electrically connected by a longer metal wire to the external terminal provided on the substrate. This may make it impossible to transmit high frequency signals. Furthermore, an additional relay element is needed to connect the control element to the external terminal. This may increase the manufacturing cost. Thus, there is demand for a small and cost-effective semiconductor device capable of improving the high frequency characteristics.

### BRIEF DESCRIPTION OF THE DRAWINGS

FIG. 1 is a schematic cross-sectional view illustrating a semiconductor device according to a first embodiment;

FIGS. 2A to 5 are schematic cross-sectional views illustrating a manufacturing process of the semiconductor device according to the first embodiment;

FIG. 6 is a schematic cross-sectional view illustrating a semiconductor device according to a variation of the first embodiment

FIG. 7 is a schematic cross-sectional view illustrating a semiconductor device according to an alternative variation of the first embodiment;

FIG. 8 is a schematic cross-sectional view illustrating a semiconductor device according to a second embodiment;

FIG. 9 is a schematic cross-sectional view illustrating a semiconductor device according to a variation of the second embodiment;

FIG. 10 is a schematic cross-sectional view illustrating a semiconductor device according to an alternative variation of the second embodiment;

FIGS. 11A and 11B are schematic cross-sectional views illustrating a manufacturing process of the semiconductor device according to the variation of the second embodiment;

FIG. 12 is a schematic cross-sectional view illustrating a semiconductor device according to a third embodiment;

FIG. 13 is a schematic cross-sectional view illustrating a semiconductor device according to a fourth embodiment.

### DETAILED DESCRIPTION

In general, according to an embodiment, a semiconductor device includes a substrate, a control element provided on the substrate, a resin provided on the control element and a memory element provided above the control element. The memory element is in contact with the resin and electrically connected to the control element provided within a region therebeneath in plan view parallel to a surface of the substrate.

Embodiments of the invention will now be described with reference to the drawings. In the following embodiments, like portions in the drawings are labeled with like reference numerals, and the detailed description thereof is omitted as appropriate. The different portions are described.

### First Embodiment

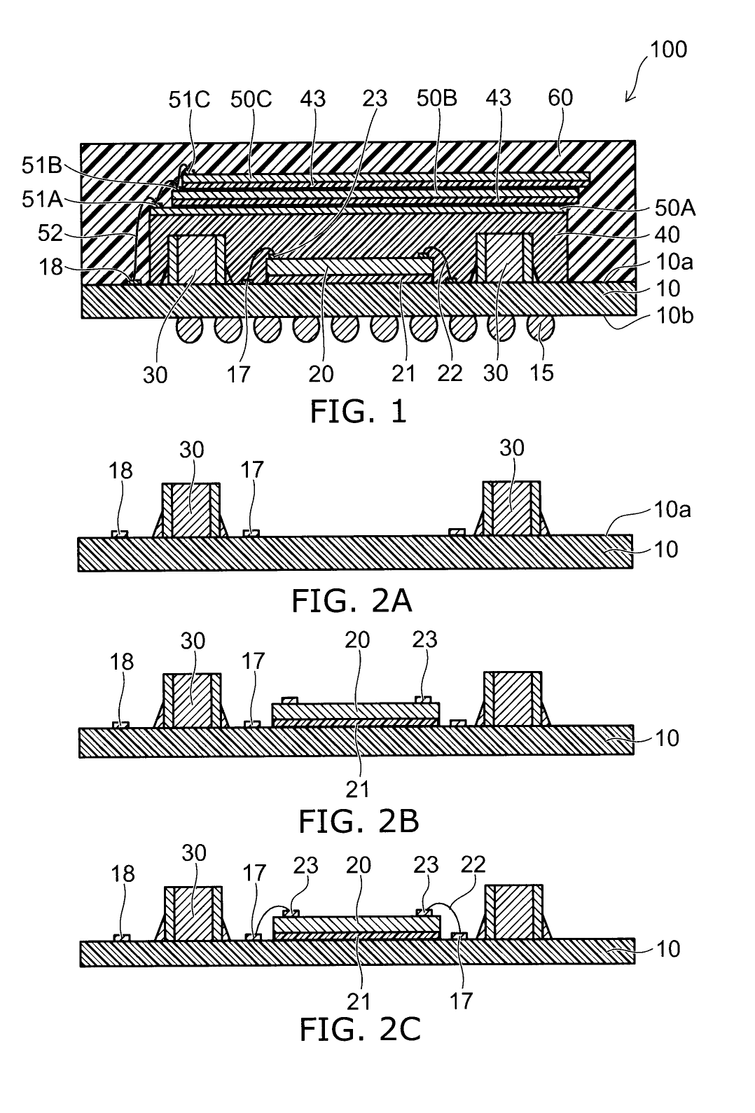

FIG. 1 is a schematic view showing a cross section of a semiconductor device 100 according to a first embodiment. The semiconductor device 100 illustrated herein is a semiconductor memory device housed in a semiconductor package of the so-called BGA (ball grid array) type.

The semiconductor device 100 includes memory elements 50A-50C, a control element 20, and a passive component 30.

The memory elements 50A-50C are e.g. NAND flash memories. The control element 20 is a memory controller for controlling the operation of the memory elements 50A-50C. The passive component 30 is a circuit component such as resistor and capacitor. Here, the memory elements 50A-50C are the largest in area as viewed from above the top surface.

As shown in FIG. 1, the semiconductor device 100 includes a substrate 10, a control element 20 arranged on the substrate 10, and a passive component 30 arranged on the substrate 10.

The control element 20 is mounted on the front surface 10a of the substrate 10 via an adhesive layer 21 provided on the back surface of the control element 20. The electrode pad 23 of the control element 20 is electrically connected by a metal wire 22 to the connection terminal 17 provided on the front surface 10a of the substrate 10.

The passive component 30 is soldered to the front surface 10a of the substrate 10. Simultaneously, the passive component 30 is connected to an interconnection (not shown) provided on the front surface 10a of the substrate 10.

Furthermore, the control element 20 and the passive component 30 are covered with an insulative resin 40. The memory element 50A is in contact with the insulative resin 40 and arranged above the control element 20 and the passive component 30.

As shown in FIG. 1, the memory elements 50A-50C are stacked with stepwise displacement so as to expose electrode pads 51. The electrode pads 51A-51C provided on one end are connected by a metal wire 52 to the connection terminal 18 provided on the front surface 10a of the substrate 10. Here, as viewed from above the top surface, the control element 20 and the passive component 30 are arranged in the region immediately below the memory elements 50A-50C. That is, the semiconductor memory device can be downsized.

The connection terminals 17 and 18 are electrically connected to solder balls 15 provided on the back surface 10b of the substrate 10 via an interconnection layer (not shown) formed inside the substrate 10. The solder balls 15 are connected to an external circuit and electrically connect the memory elements 50A-50C and the control element 20 to the external circuit. Here, the passive component 30 is arranged on the substrate 10. This can shorten the distance between the passive component 30 and the solder balls 15 receiving input of external signals. As a result, noise can be effectively removed.

The connection terminal 17 and the connection terminal 18 are electrically connected by an interconnection (not shown) provided on the front surface 10a of the substrate 10. Thus, the control element 20 controls the memory elements 50A-50C.

Furthermore, the memory elements 50A-50C, the control element 20, and the passive component 30 are covered with a sealing resin 60, and thereby sealed from the external environment.

Next, a process for manufacturing the semiconductor device 100 is described with reference to FIGS. 2A to 5.

As shown in FIG. 2A, a passive component 30 is mounted on the front surface 10a of a substrate 10. Specifically, solder paste is printed at a prescribed position on the front surface 10a where the passive component 30 is to be arranged. Then, the passive component 30 is placed on the solder paste and soldered by the reflow process.

The substrate 10 is e.g. a glass epoxy substrate including multilayer interconnection.

Next, as shown in FIG. 2B, a control element 20 is mounted on the front surface 10a of the substrate 10. On the back surface of the control element 20, for instance, an adhesive layer 21 including a thermosetting resin such as epoxy resin is provided. Thus, the control element 20 can be pressure bonded to the front surface 10a. Furthermore, the substrate 10 is heated to cure the adhesive layer 21. Thus, the control element 20 is fixed.

Then, as shown in FIG. 2C, the electrode pad 23 of the control element 20 is connected to the connection terminal 17 by a metal wire 22.

Thus, by using a metal wire 22 to connect between the connection terminal 17 and the electrode pad 23, the type of the control element 20 can be arbitrarily selected. For instance, no metal wire is used for a control element of the so-called flip chip type. For such a control element, the spacing of the electrode pads needs to be matched with the spacing of the connection terminals 17. Thus, a substrate dedicated to the control terminal or a substrate compliant with given standards is used in such a case.

Furthermore, for a control element of the so-called flip chip type, the pitch of the electrode pads needs to be matched with the pitch of interconnection layers formed inside the substrate 10. Thus, a control element with electrode pads mismatched to the interconnection pitch cannot be arranged. For example, in the control element 20 used to control memory elements, the pitch of the electrode pads 23 may be shorter than the pitch of interconnection layers. In the embodiment, it is possible to arrange the control element 20 in which the pitch of the electrode pads 23 is shorter than the pitch of interconnection layers of the substrate 10 by using a metal wire 22 to connect between the connection terminal 17 and the electrode pad 23.

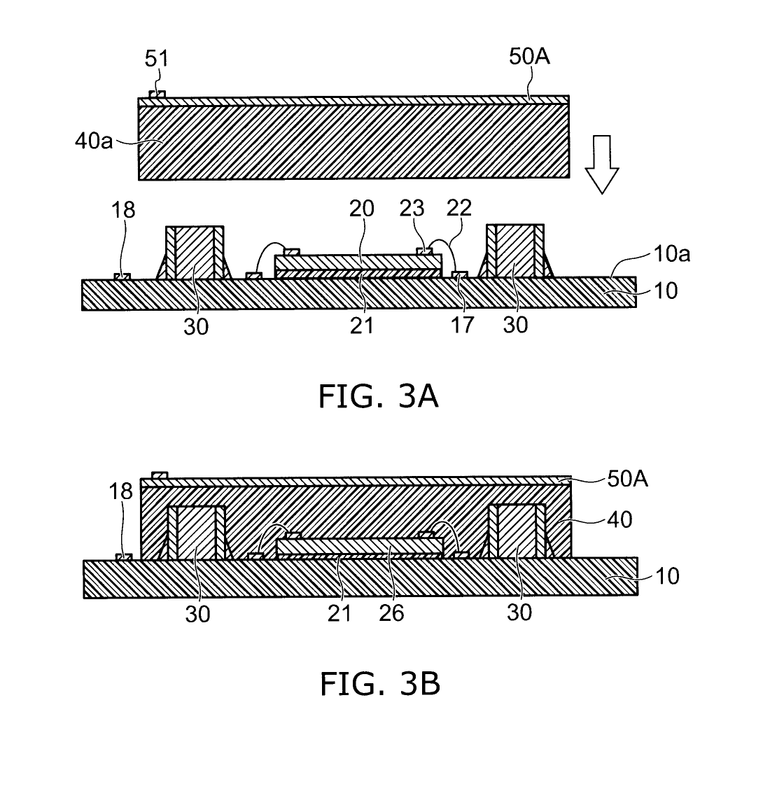

Next, as shown in FIG. 3A, a memory element 50A is mounted on the front surface 10a of the substrate 10. On the back surface of the memory element 50A, a resin layer 40a is provided. The resin layer 40a includes e.g. a thermosetting epoxy resin. The resin layer 40a can be provided in the state of the so-called B stage (semicured state) in which the resin is soft with low elastic modulus.

Hence, as shown in FIG. 3B, the memory element 50A is mounted on the substrate 10, enclosing the control element 20 and the passive component 30 in the resin layer 40a. Here, the soft resin layer 40a may prevent the metal wire 22 from deformation, connecting the electrode pad 23 of the control element 20 to the connection terminal 17.

Next, the substrate 10 is heated. Thus, the resin layer 40a covering the control element 20 and the passive component 30 is cured to form an insulative resin 40. As a result, the memory element 50A is fixed above the control element 20 and the passive component 30 in the state of being in contact with the insulative resin 40. This allows memory elements 50B and 50C to be stacked on the memory element 50A.

The resin layer 40a can be formed by e.g. sticking a DAF (die attach film) on the back surface of a semiconductor wafer provided with the memory element 50A. Alternatively, the resin layer 40a may be formed by applying an adhesive containing a thermosetting resin to the back surface of the semiconductor wafer and drying it.

The viscosity before curing of the resin layer 40a can be set to e.g. 1-10000 Pa·s, and the elastic modulus after curing can be set to e.g. 1-1000 MPa.

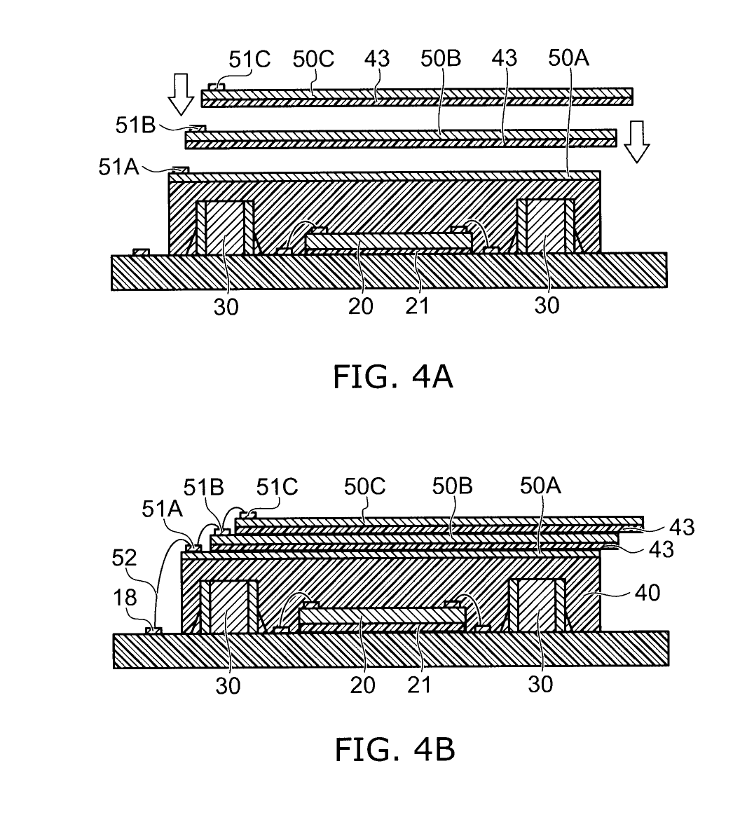

Next, memory elements 50B and 50C are sequentially mounted as shown in FIG. 4A. An adhesive layer 43 is provided on the back surface of the memory elements 50B and 50C. Thus, the memory elements 50B and 50C can be stuck on the front surface of the memory element 50A and the front surface of the memory element 50B, respectively.

Then, as shown in FIG. 4B, the memory elements 50A-50C are stacked stepwise so as to expose electrode pads 51A-51C provided on one end thereof, respectively.

Next, the adhesive layer 43 is cured by heating the substrate 10 to fix the memory elements 50A-50C stacked stepwise. Then, the electrode pads 51A-51C are connected to the connection terminal 18 by a metal wire 52.

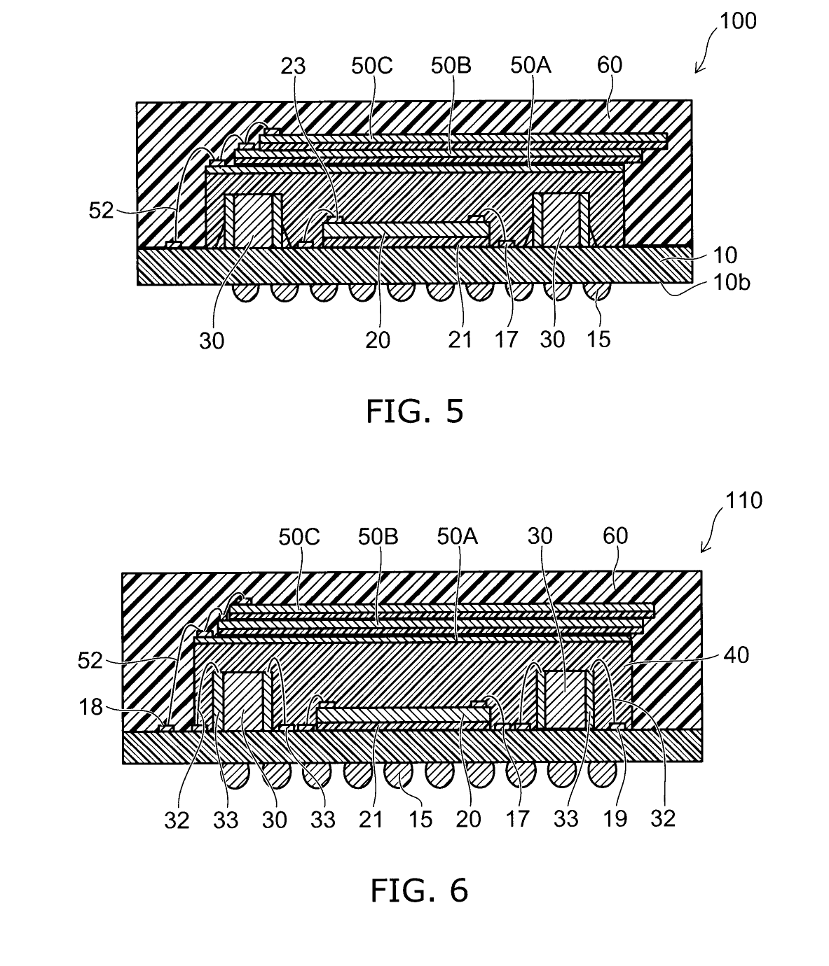

Next, as shown in FIG. 5, a sealing resin 60 is molded on the substrate 10 to resin seal the memory elements 50A-50C, the control element 20, and the passive component 30. Then, solder balls 15 can be attached to the back surface side of the substrate 10 to complete the semiconductor device 100.

In the above semiconductor device 100, the control element 20 and the passive component 30 are three-dimensionally arranged below the memory element 50A. This can minimize the package size depending on the size of the memory element. On the other hand, the metal wire 22 can be shortened for connecting the electrode pad 23 of the control element 20 to the connection terminal 17 provided on the front surface 10a of the substrate 10. Thus, degradation can also be suppressed in high frequency characteristics.

Furthermore, the resin layer 40a provided on the back surface of the memory element 50A can be used to form an insulative resin 40 covering the control element 20 and the passive component 30. This can simplify the assembly of the semiconductor device 100.

FIG. 6 is a schematic view showing a cross section of a semiconductor device 110 according to a variation of the first embodiment. The semiconductor device 110 is different from the semiconductor device 100 shown in FIG. 1 in that the electrode 33 of the passive component 30 is connected by a metal wire 32 to the interconnection 19 provided on the substrate 10. The electrode 33 of the passive component 30 is desirably plated with e.g. gold to enhance adhesion to the metal wire.

Thus, by changing the electrical connection means of the passive component 30 to a metal wire 32, the high temperature reflow process can be omitted. Furthermore, wire bonding can be performed in the same assembly process as that for the control element 20. This can simplify the manufacturing process.

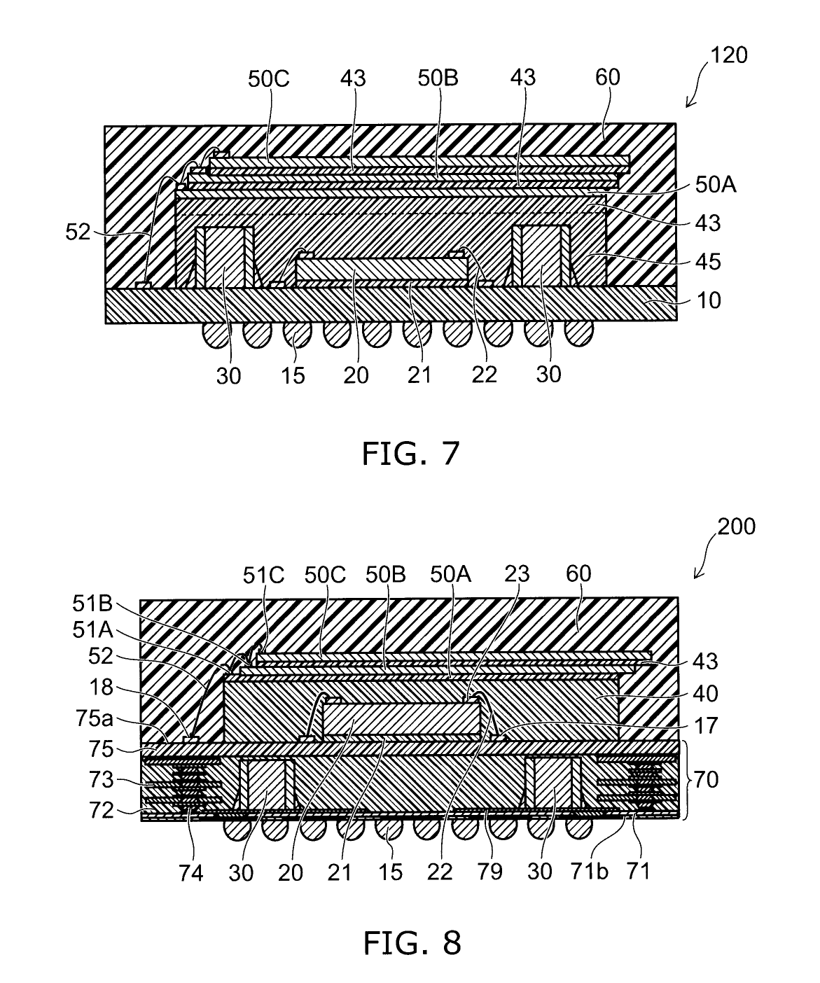

FIG. 7 is a schematic view showing a cross section of a semiconductor device 120 according to an alternative variation of the first embodiment. The semiconductor device 120 is different from the semiconductor device 100 shown in FIG. 1 in that the memory element 50A is mounted on an insulative resin 45 covering the control element 20 and the passive component 30. The memory element 50A includes an adhesive layer 43 provided on its back surface, like the memory elements 50B and 50C stacked thereon. Thus, the memory element 50A can be stuck on the insulative resin 45.

More specifically, in the semiconductor device 120 according to this variation, an insulative resin 45 covering the control element 20 and the passive component 30 is molded beforehand. Then, the memory element 50A is mounted thereon. The memory element 50A is in contact with the insulative resin 45 via the adhesive layer 43 provided on the back surface thereof.

In the semiconductor device 120, there is no need to provide a thick resin layer 40a (see FIG. 3A) on the back surface of the memory element 50A. This can simplify the manufacturing process.

### Second Embodiment

FIG. 8 is a schematic view showing a cross section of a semiconductor device 200 according to a second embodiment.

As shown in FIG. 8, the semiconductor device 200 is different from the semiconductor device 100 shown in FIG. 1 in that the passive component 30 is arranged inside the substrate 70.

The substrate 70 includes a multilayer structure in which insulating layers 72 and interconnection layers 73 are alternately stacked between a first base 71 and a second base 75. For instance, the first base 71 and the second base 75 are glass epoxy substrates. The insulating layer 72 can be made of an insulating film formed by composite molding of epoxy resin with carbon fibers.

A plurality of interconnection layers 73 are arranged between the first base 71 and the second base 75. This interconnection layer 73 can be made of copper foil. Vertically adjacent interconnection layers 73 are electrically connected by a bump 74. Thus, the interconnection (not shown) provided on the front surface 75a of the second base is electrically connected to the solder ball 15 attached to the back surface 71b of the first base. These interconnection layers 73 and bumps 74 are integrated by e.g. thermocompression bonding. Here, instead of using interconnection layers 73 and bumps 74, a through hole may be formed so as to penetrate through the substrate 70 between the first base 71 and the second base 75. A conductor may be formed in this through hole to electrically connect the interconnection provided on the front surface 75a of the second base to the solder ball 15 attached to the back surface 71b of the first base.

The interconnection on the front surface 75a of the second base is connected to the connection terminals 17 and 18. Thus, the control element 20 and the memory elements 50A-50C are electrically connected to the solder balls 15.

On the other hand, the passive component 30 is incorporated between the first base 71 and the second base 75. Through the interconnection 79 provided on the front surface of the first base 71 and the interconnection layers 73, the passive component 30 is connected to the interconnection provided on the front surface of the second base 75. An insulating layer 72 is arranged between the first base 71 and the second base 75 so as to cover the interconnection layers 73, the bumps 74, and the passive component 30, and integrated by thermocompression bonding.

For instance, as shown in FIG. 8, the passive component 30 is bonded onto the first base and electrically connected to the interconnection 79.

As shown in FIG. 8, a control element 20 is mounted on the second base 75. The electrode pad 23 of the control element 20 is electrically connected via a metal wire 22 to the connection terminal 17 arranged on the second base 75a. The control element 20 is covered with an insulative resin 40. A memory element 50A is arranged in contact with the insulative resin 40. Memory elements 50B and 50C are stacked on the memory element 50A.

Also in the semiconductor device 200 according to this embodiment, the memory element 50A is arranged above the control element 20 and the passive component 30. Thus, the package can be downsized. The electrode pad 23 of the control element 20 is connected by a short metal wire 22 to the connection terminal 17, which is part of the interconnection provided on the front surface 75a of the second base. Thus, degradation can be suppressed in the high frequency characteristics. Furthermore, the electrode pad 23 of the control element 20 is electrically connected to the second base 75a located at the top of the substrate 77. This can shorten the wiring distance between the memory element 50A and the control element 20. As a result, the operation of the semiconductor device 200 can be accelerated.

Furthermore, the passive component 30 is incorporated in the substrate 70. This can simplify the assembly process of the semiconductor device 200, and reduce the manufacturing cost. Furthermore, the passive component 30 is arranged on the first base 71. This can shorten the distance between the passive component 30 and the solder balls 15 receiving input of external signals. As a result, noise can be effectively removed.

Furthermore, the control element 20 shown in FIG. 8 may also be incorporated in the substrate 70. This can further simplify the assembly process.

However, incorporating the control element 20, which is an active element, in the substrate 70 may result in decreasing the yield of the semiconductor device 200 and increasing the manufacturing cost. For instance, if the control element 20 is broken in the process of manufacturing the substrate 70, the trouble may not be detected until the product inspection performed after the memory elements 50A-50C are mounted. Hence, there is a danger that the memory elements 50A-50C and the mounting cost thereof are wasted.

Furthermore, in the process of manufacturing the substrate 70, if electrolytic plating is used to form the interconnection, a current may flow in the control element 20 and break it. Thus, instead of electrolytic plating, it is necessary to use electroless plating. However, electroless plating is expensive and causes another problem of increasing the manufacturing cost of the substrate 70.

In contrast, in the semiconductor device 200 according to the embodiment, whereas the passive component 30 is incorporated in the substrate 70, the control element 20 is mounted on the substrate 70. Thus, the wiring of the substrate 70 can be formed by electrolytic plating. Furthermore, the passive component 30 is scarcely broken in the process of manufacturing the substrate 70. Thus, there is no danger of decreasing the yield.

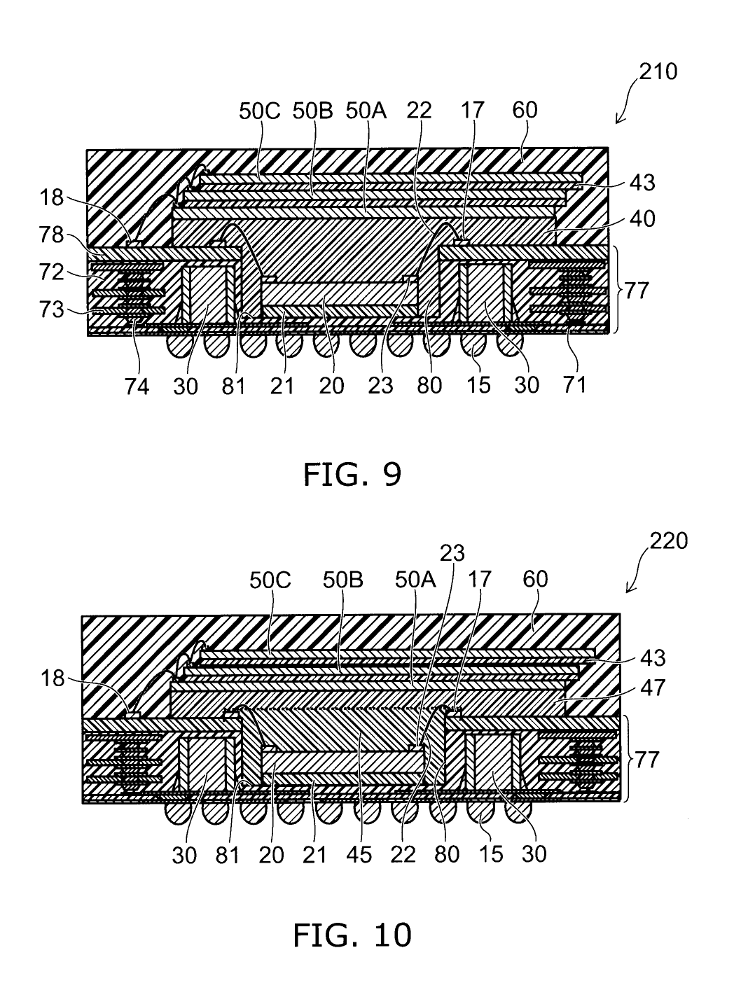

FIG. 9 is a schematic view showing a cross section of a semiconductor device 210 according to a variation of the second embodiment. In the semiconductor device 210, as in the semiconductor device 200 shown in FIG. 8, the passive component 30 is arranged inside the substrate 75. On the other hand, the semiconductor device 210 is different from the semiconductor device 200 in that the control element 20 is arranged on the bottom surface 81 of a recess 80 provided in the substrate 77.

As shown in FIG. 9, the control element 20 is covered with an insulative resin 40 filling the recess 80. The electrode pad 23 of the control element 20 is connected by a metal wire 22 to the connection terminal 17 of the second base 78. The memory element 50A is arranged above the passive component 30 incorporated in the substrate 77 and the control element 20. The memory element 50A is mounted in contact with the insulative resin 40. As shown in FIG. 3A, the insulative resin 40 can be formed by providing a resin layer 40a on the back surface of the memory element 50A.

As shown in FIG. 9, the recess 80 is formed toward the first base 71 from an opening provided in the second base 78. The depth of the recess 80 can be made deeper than the thickness of the control element 20. The connection terminal 17 is provided around the opening of the recess 80 on the surface of the second base 78 opposite to the insulating layer 72.

The semiconductor device 210 according to the variation of the second embodiment has a similar effect to the second embodiment. That is, the electrode pad 23 of the control element 20 is electrically connected to the second base 75a located at the top of the substrate 77. This can shorten the wiring distance between the memory element 50A and the control element 20. As a result, the operation of the semiconductor device 200 can be accelerated. Furthermore, in the semiconductor device 210, the control element 20 is arranged in the recess of the substrate 77. Thus, the thickness of the package can be made thinner than that of the semiconductor device 200 shown in FIG. 8.

FIG. 10 is a schematic view showing a cross section of a semiconductor device 220 according to an alternative variation of the second embodiment. The semiconductor device 220 is the same as the semiconductor device 210 shown in FIG. 9 in that the passive component 30 is incorporated in the substrate 77 and that the control element 20 is arranged in the recess 80 provided in the substrate 77.

On the other hand, in the semiconductor device 220, the inside of the recess 80 is filled with an insulative resin 45, and the control element 20 is covered with the insulative resin 45. The memory element 50A is mounted in contact with the insulative resin 45. In this point, the semiconductor device 220 is different from the semiconductor device 210. The memory element 50A includes an adhesive layer 47 provided on its back surface. The memory element 50A is stuck on the insulative resin 45 via the adhesive layer 47.

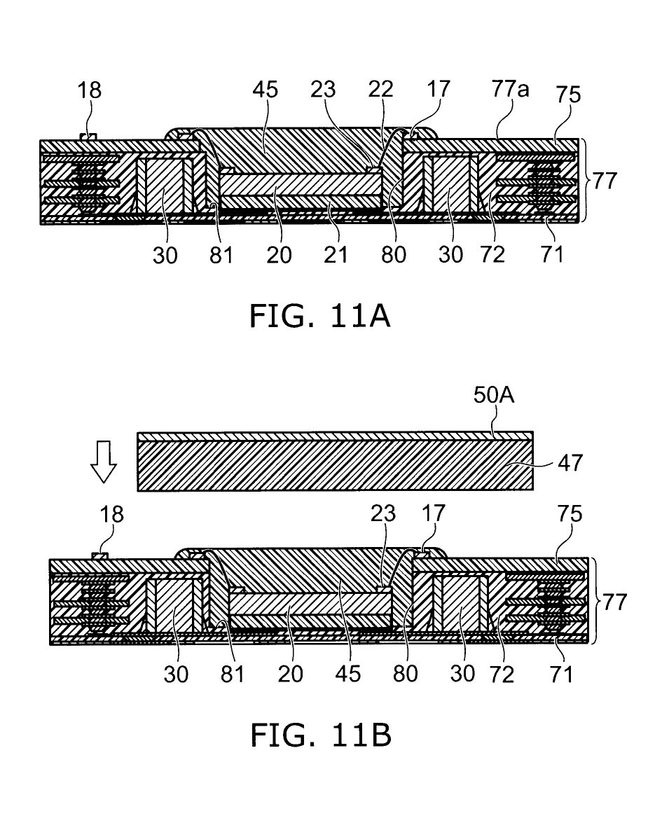

FIGS. 11A and 11B are schematic sectional views showing part of a process for manufacturing the semiconductor device 220.

First, a substrate 75 with a passive component 30 incorporated therein is prepared. Subsequently, a recess 80 for exposing the upper surface of the first base 71 is formed.

As shown in FIG. 11A, a control element 20 is mounted on the bottom surface 81 (the upper surface of the first base 71) of the recess 80 provided in the substrate 75. On the back surface of the control element 20, for instance, an adhesive layer 21 including a thermosetting resin is provided. Thus, the control element 20 can be pressure bonded to the bottom surface 81 of the recess 80. Then, the substrate 75 is heated to cure the adhesive layer 21. Thus, the control element 20 can be fixed to the bottom surface 81 of the recess 80.

Next, the electrode pad 23 of the control element 20 is connected by a metal wire 22 to the connection terminal 17 provided on the front surface 77a of the substrate 77. Subsequently, in the variation of the second embodiment, manufacturing can be performed by following the process of FIGS. 3A to 5. Subsequently, the inside of the recess 80 is filled with an insulative resin 45. The insulative resin 45 can be e.g. a thermosetting epoxy resin. The epoxy resin can be one with low viscosity dispersed in a solvent such as γ-butyrolactone. This can suppress deformation of the metal wire 22 and generation of voids and the like. Thus, the inside of the recess 80 can be uniformly filled.

Next, the substrate 77 is heated to evaporate the solvent and, furthermore, to cure the epoxy resin.

Next, as shown in FIG. 11B, a memory element 50A is mounted above the control element 20 and the passive component 30.

On the back surface of the memory element 50A, for instance, a B-stage adhesive layer 47 is provided. Thus, the memory element 50A can be adhesively stuck on the front surface of the insulative resin 45. The adhesive layer 47 can be formed by e.g. application of a thermosetting resin. Alternatively, the adhesive layer 47 may be formed by sticking a DAF.

Furthermore, as shown in FIG. 10, memory elements 50B and 50C can be stacked. The adhesive layer 43 provided on the back surface of the memory elements 50B and 50C may be the same as the adhesive layer 47 provided on the memory element 50A. Alternatively, the adhesive layer 47 may be made thicker than the adhesive layer 43.

The semiconductor device 220 according to the alternative variation of the second embodiment has a similar effect to the second embodiment. Furthermore, as described above, the viscosity is decreased at the filling time of the insulative resin 45 covering the control element 20. This can suppress deformation of the metal wire 22 of the control element 20 and generation of voids inside the recess 80.

Furthermore, the insulative resin 45 filling the recess 80 is provided independently of the adhesive layer 47 for sticking the memory element 50A. Hence, there is no need to fill the recess 80 with the resin layer provided on the back surface of the memory element 50A as in the semiconductor device 210 shown in FIG. 9. Thus, the adhesive layer 47 can be thinned. Accordingly, the memory element 50A can use the same adhesive layer as the memory elements 50B and 50C stacked thereon. This can simplify the process for manufacturing the memory element 50A.

### Third Embodiment

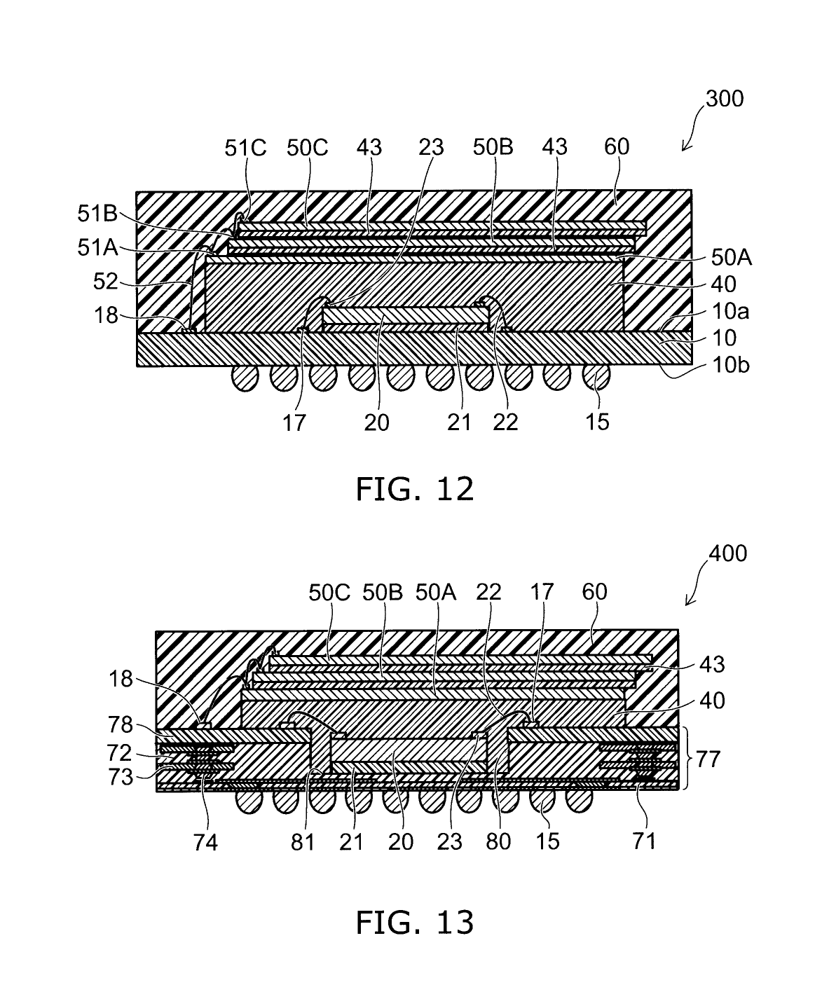

FIG. 12 is a schematic view showing a cross section of a semiconductor device 300 according to a third embodiment. The semiconductor device 300 is different from the first embodiment in that the passive component 30 is not formed. Such an embodiment can also achieve a similar effect to the first embodiment.

### Fourth Embodiment

FIG. 13 is a schematic view showing a cross section of a semiconductor device 400 according to a fourth embodiment. The semiconductor device 400 is different from the second embodiment in that the passive component 30 is not formed. Such an embodiment can also achieve a similar effect to the second embodiment.

The semiconductor devices according to the first to fourth embodiments have been described above. However, the embodiments are not limited thereto. For instance, the number of memory elements installed on the semiconductor device is not limited to three. The number of memory elements stacked may be more than three, or less than three.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a control element provided on the substrate;
a resin provided on the control element; and
a memory element provided above the control element, the memory element being in contact with the resin and electrically connected to the control element provided within a region beneath the memory element in plan view parallel to a surface of the substrate.

2. The device according to claim 1, further comprising:
a passive component provided on the substrate or inside the substrate,
wherein the passive component is provided in a region beneath the memory element.

3. The device according to claim 2, further comprising:
a plurality of memory elements electrically connected to the control element,
wherein the plurality of memory elements are stacked with stepwise displacement, and
the control element and the passive component are provided within a region beneath the plurality of memory elements in plan view parallel to a surface of the substrate.

4. The device according to claim 2, wherein
the passive component is provided on the substrate, and
the resin is provided on the control element and the passive component.

5. The device according to claim 2, wherein
the substrate includes a first base, a second base and an insulating layer provided therebetween,
the control element and the memory element are provided on a surface of the second base opposite to the insulating layer, and
the passive component is provided between the first base and the second base and covered with the insulating layer.

6. The device according to claim 1, wherein the control element is connected by a metal wire to a terminal provided on the substrate.

7. The device according to claim 1, wherein the passive component is connected by a metal wire to an interconnection provided on the substrate.

8. The device according to claim 1, wherein the control element and the memory element are electrically connected via an interconnection provided on the substrate, and the control element controls the memory element.

9. The device according to claim 1, wherein the control element is provided on a bottom surface of a recess in the substrate.

10. The device according to claim 9, wherein the recess is deeper than thickness of the control element.

11. The device according to claim 9, wherein the passive component is provided inside the substrate.

12. The device according to claim 9, wherein
the substrate includes a first base, a second base and an insulating layer provided between the first base and second base,
the recess is provided toward the first base from an opening provided in the second base, and
the passive component is provided between the first base and the second base and covered with the insulating layer.

13. The device according to claim 12, wherein the control element is connected by a metal wire to a terminal provided on a surface of the second base opposite to the insulating layer.

14. The device according to claim 12, wherein the passive component is provided on the first base and electrically connected to a terminal provided on a surface of the second base opposite to the insulating layer.

15. The device according to claim 1, wherein the resin includes a thermosetting ingredient.

16. The device according to claim 1, further comprising:
an adhesive layer between the control element and the substrate.

17. A method for manufacturing a semiconductor device comprising:
preparing a substrate including a control element and a passive component, the control element being arranged on the substrate and a passive component being arranged on the substrate or inside the substrate;
preparing a memory element with a resin layer on a back surface;
sticking a memory element on the substrate via the resin layer covering the control element.

18. The method according to claim 17, wherein the resin layer is made of a thermosetting resin in semicured state.

19. The method according to claim 17, wherein the resin layer is a die attached film.

20. A method for manufacturing a semiconductor device comprising:
preparing a substrate including a control element and a passive component, the control element being arranged on the substrate and a passive component being arranged on the substrate or inside the substrate;
preparing a memory element with a adhesive layer provided on a back surface;
covering the control element with a resin; and
sticking a memory element on a surface of the resin via the adhesive layer.
